(19) United States
(12) Patent Application Publication
(10) Pub. No.: US 2025/0262774 A1
(43) Pub. Date: Aug. 21, 2025

(54) SLURRY FILTER REPLACEMENT ROBOT

(71) Applicant: SAMSUNG ELECTRONICS CO., LTD., Suwon-si (KR)

(72) Inventors: Shibaek PARK, Suwon-si (KR); Han Sung KIM, Suwon-si (KR); Gi-Seong KIM, Suwon-si (KR); Sung Hun JEONG, Suwon-si (KR)

(73) Assignees: SAMSUNG ELECTRONICS CO., LTD., Suwon-si (KR); INDUSTRY-ACADEMIC COOPERATION FOUNDATION OF KYUNGNAM UNIVERSITY, Changwon-si (KR)

(21) Appl. No.: 18/815,043

(22) Filed: Aug. 26, 2024

(30) Foreign Application Priority Data
Feb. 19, 2024 (KR) 10-2024-0023588

(51) Int. Cl. B25J 11/00; B25J 15/00; B25J 19/02

(52) U.S. Cl. CPC B25J 11/005; B25J 15/0038; B25J 19/02

(57) ABSTRACT

A slurry filter replacement robot for replacing a first filter at an operating station includes one or more manipulators, a support frame disposed in a lower portion of the one or more manipulators and configured to support the one or more manipulators, a loader coupled with the support frame and configured to load the first filter and a second filter thereon, and a mover disposed in a lower portion of the support frame and configured to move the support frame. Each of the one or more manipulators includes an arm and a robot tool coupled with a first side of the arm. Each of the one or more manipulators is configured to replace the first filter disposed on the operating station with the second filter loaded on the loader.

### CROSS-REFERENCE TO RELATED APPLICATIONS

This application claims benefit of priority under 35 U.S.C. § 119 to Korean Patent Application No. 10-2024-0023588, filed on Feb. 19, 2024, in the Korean Intellectual Property Office, the disclosure of which is incorporated by reference herein in its entirety.

### BACKGROUND

### 1. Field

The present disclosure relates generally to semiconductor cleaning processes, and more particularly, to a slurry filter replacement robot.

### 2. Description of Related Art

A semiconductor chemical mechanical polishing (CMP) process may refer to a process of refining and/or smoothing curves of a wafer surface and may include a process of polishing and/or planarizing a thin film surface of a wafer that may have irregularities and/or curves through chemical and/or mechanical elements.

The semiconductor CMP process may utilize the principle that when parts having different heights in a chip are in contact with a pad, the parts may receive different pressures, and a part that is relatively high may be first polished by a high pressure. The semiconductor CMP process may be performed with a polishing liquid, which may be referred to as a slurry, which may be distributed on a contact surface to potentially prevent and/or mitigate scratches on the wafer surface and to potentially compensate for instability in a process control.

CMP slurries may be and/or may include solutions that may include combinations of polishing particles that may perform mechanical polishing, chemical additives that may perform chemical polishing, and/or various other functions. For example, metal oxide ceramic materials, such as, but not limited to, silica and ceria, may be used as polishing particles, and the types and/or combinations of chemical additives may be very diverse.

The CMP slurries may vary depending on a material of a thin film to be polished, and may be divided and/or categorized into an insulating film slurry, a metal film slurry (e.g., copper (Cu), tungsten (W), or the like), and/or an organic film slurry (e.g., an amorphous carbon (C) film).

In a slurry supply process, in order to minimize impurities included in slurries, slurries may be supplied through a slurry filter. A filter for filtering slurries used in a CMP process may need to be replaced at regular intervals.

However, when an operator manually replaces the slurry filter, since the operator may need to separate and fasten the slurry filter by using separate tools, a significant amount of time and/or expenses may be consumed in a replacement process, and as a result, the efficiency of a slurry filter replacement job is not high. Furthermore, additional contamination and equipment damage may occur during a slurry filter replacement process, as well as, the operator may be exposed to danger due to chemical handling.

### SUMMARY

One or more example embodiments of the present disclosure provide a slurry filter replacement robot that replaces a slurry filter disposed at an operating station by using the slurry filter replacement robot, thereby preventing or mitigating a problem in that an operator is exposed to danger during a replacement process, and minimizing additional contamination and equipment damage that may occur during the slurry filter replacement process by cleaning surrounding equipment using a cleaning device disposed inside the operating station during the replacement process.

According to an aspect of the present disclosure, a slurry filter replacement robot for replacing a first filter at an operating station includes one or more manipulators, a support frame disposed in a lower portion of the one or more manipulators and configured to support the one or more manipulators, a loader coupled with the support frame and configured to load the first filter and a second filter thereon, and a mover disposed in a lower portion of the support frame and configured to move the support frame. Each of the one or more manipulators includes an arm and a robot tool coupled with a first side of the arm. Each of the one or more manipulators is configured to replace the first filter disposed on the operating station with the second filter loaded on the loader.

According to an aspect of the present disclosure, a slurry filter replacement robot for replacing a first filter at an operating station includes a first manipulator including a first arm and a first robot tool coupled with a side of the first arm, a second manipulator including a second arm and a second robot tool coupled with a side of the second arm, a support frame disposed in a lower portion of the first manipulator and the second manipulator, a loader coupled with the support frame and configured to load the first filter and a second filter thereon, and a mover disposed in a lower portion of the support frame and configured to move the support frame. The second manipulator is configured to replace the first filter disposed on the operating station with the second filter loaded on the loader.

According to an aspect of the present disclosure, a slurry filter replacement robot for replacing a first filter disposed at an operating station includes a manipulator, a support frame disposed in a lower portion of the manipulator, a loader coupled with the support frame and configured to load the first filter and a second filter, and a mover disposed in a lower portion of the support frame and configured to move the support frame. The manipulator includes a robot tool configured to grip a ball of the operating station, a nut of the operating station, and the first filter, and a third arm having a first side coupled with the robot tool. The manipulator is configured to replace the first filter disposed on the operating station with the second filter loaded on the loader. The ball of the operating station is coupled with a head disposed on an operating table of the operating station. The nut of the operating station is disposed between the ball and the head and is configured to couple the ball to the head.

According to embodiments, the slurry filter replacement robot may be used to replace a used slurry filter (e.g., a first filter) disposed at the operating station with a new slurry filter (e.g., a second filter), thereby potentially increasing the efficiency of the slurry filter replacement operation, and minimizing equipment damage and human damage.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 is a diagram showing the overall configuration of a slurry filter replacement robot, according to an embodiment;

FIG. 2 is a diagram showing the configuration of a slurry filter replacement robot, according to an embodiment;

FIG. 3 is a diagram showing the overall configuration of a slurry filter replacement robot, according to another embodiment;

FIG. 4 is a diagram illustrating the slurry filter replacement robot of FIG. 3, according to an embodiment;

FIG. 5 is a diagram depicting manipulators of the slurry filter replacement robot of FIG. 4, according to an embodiment;

FIG. 6 is a diagram illustrating manipulators of the slurry filter replacement robot of FIG. 4, according to an embodiment;

FIG. 7 is a diagram depicting a structure in which a slurry filter is coupled with an operating station in a slurry filter replacement robot, according to an embodiment;

FIG. 8 is a diagram illustrating a process of coupling the slurry filter to the operating station, according to an embodiment;

FIG. 9 is a diagram depicting a structure in which a slurry filter is coupled with an operating station in a slurry filter replacement robot, according to an embodiment;

FIG. 10 is a diagram illustrating a process of coupling the slurry filter to the operating station, according to an embodiment;

FIGS. 11 to 14 are diagrams depicting a process in which the slurry filter replacement robot replaces a slurry filter, according to an embodiment;

FIG. 15 is a diagram showing the overall configuration of a slurry filter replacement robot, according to an embodiment;

FIG. 16 is a diagram illustrating the slurry filter replacement robot of FIG. 15, according to an embodiment;

FIG. 17 is a diagram depicting a manipulator of the slurry filter replacement robot of FIG. 15, according to an embodiment;

FIGS. 18 to 21 are diagrams illustrating a process in which the slurry filter replacement robot replaces a slurry filter, according to an embodiment; and

FIG. 22 is a diagram depicting a replacement process by using a slurry filter replacement robot, according to an embodiment.

### DETAILED DESCRIPTION

Hereinafter, with reference to the accompanying drawings, various embodiments of the present disclosure are described so that those skilled in the art may carry out the present disclosure. The present disclosure may be embodied in many different forms and may not be limited to the embodiments set forth herein.

In order to explain the present disclosure in the drawings, parts irrelevant to the description may be omitted, and the same reference numerals may be used for the same or similar elements throughout the specification.

In addition, since the size and thickness of each component shown in the drawings may be arbitrarily shown for convenience of description, the present disclosure is not necessarily limited to those shown. In the drawings, the thickness of layers and regions may be exaggerated for clarity. In addition, in the drawings, for convenience of explanation, thicknesses of some layers and areas may be exaggerated.

Throughout the present disclosure, when an element is referred to as being “connected” to another element, this includes not only the element being “directly connected” but also being “indirectly connected” to the other element with other members therebetween. In addition, unless explicitly described to the contrary, the word “comprise”, and variations such as “comprises” or “comprising”, may be understood to imply the inclusion of stated elements but not the exclusion of any other elements.

In addition, it is to be understood that when an element such as a layer, film, region, or substrate is referred to as being “on” another element, the element may be directly on the other element or intervening elements may also be present. In contrast, when an element is referred to as being “directly on” another element, there may be no intervening elements present. In addition, being “above” or “on” a reference part may refer to being above or below the reference part, and may not necessarily refer to being “above” or “on” in the opposite direction of gravity.

Throughout the present disclosure, when an element or view is “on a plane” may refer to when a target portion is viewed from above, and when an element or view is “on a cross section” may refer to when a cross section obtained by vertically cutting a target portion is viewed from the side.

It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

The terms “upper,” “middle”, “lower”, and the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

The embodiments herein may be described and illustrated in terms of blocks, as shown in the drawings, which carry out a described function or functions. These blocks, which may be referred to herein as units or modules or the like, or by names such as device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, and the like.

In the present disclosure, the articles “a” and “an” are intended to include one or more items, and may be used interchangeably with “one or more.” Where only one item is intended, the term “one” or similar language is used. For example, the term “a processor” may refer to either a single processor or multiple processors. When a processor is described as carrying out an operation and the processor is referred to perform an additional operation, the multiple operations may be executed by either a single processor or any one or a combination of multiple processors.

Hereinafter, a slurry filter replacement robot, according to various embodiments of the present disclosure are described with reference to the accompanying drawings.

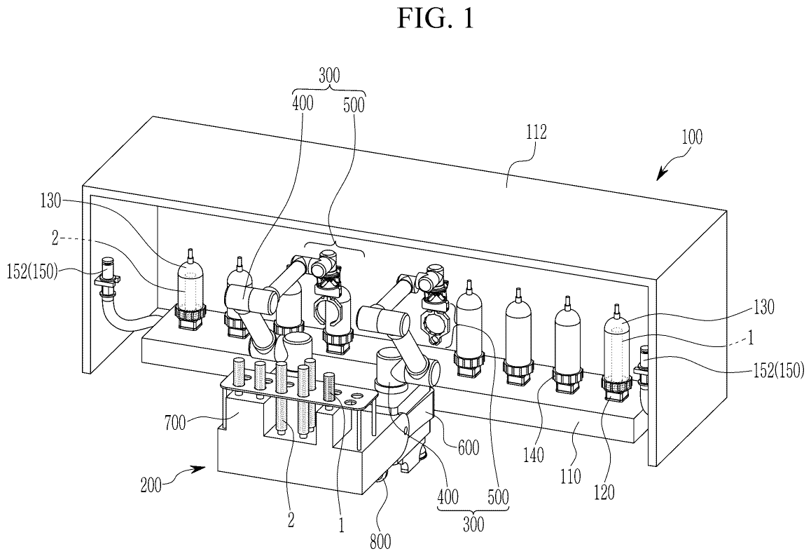

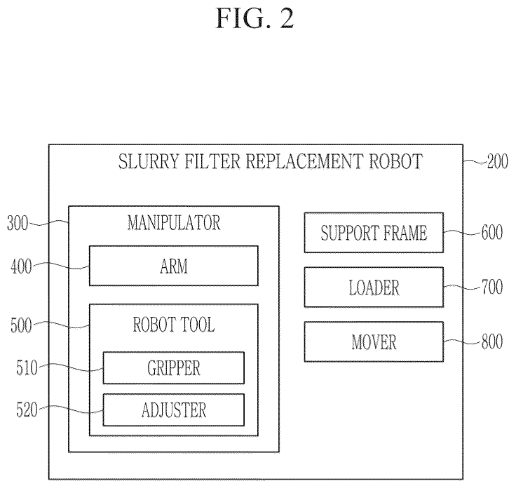

FIG. 1 is a diagram showing the overall configuration of a slurry filter replacement robot, according to an embodiment. FIG. 2 is a diagram showing the configuration of a slurry filter replacement robot, according to an embodiment.

Referring to FIGS. 1 and 2, the slurry filter replacement robot 200 may replace a first filter 1 at an operating station 100 where the first filter 1 is disposed.

The slurry filter replacement robot 200 may include one or more manipulators 300 including an arm 400 and a robot tool 500 connected to one side of the arm 400.

Although two (2) manipulators 300 are shown in FIG. 1, the present disclosure is not limited in this regard. That is, the number of manipulators 300 included in the slurry filter replacement robot 200 may not be limited. As shown in FIG. 1, the arm 400 may have the form of a multi-joint arm 400, and a position of a robot tool 500 connected to one side of the arm 400 may be adjusted by adjusting a position of the arm 400.

The slurry filter replacement robot 200 may include a support frame 600 disposed in a lower part of the manipulator 300 and configured to support the manipulator 300, a loader 700 connected to the support frame 600 and configured to load the first filter 1 and the second filter 2, and a mover 800 disposed in a lower part of the support frame 600 and configured to move the support frame 600. For example, the support frame 600 may include a structure configured to support the manipulator 300, the loader 700, and the mover 800. As another example, the mover 800 may include wheels, motors, axles, or the like configured to transport the slurry filter replacement robot 200 along the operating table 110.

The slurry filter replacement robot 200 may be configured to move close to the operating station 100 through the mover 800, and replace the first filter 1 disposed on the operating station 100 with the second filter 2 loaded in the loader 700 by using the manipulator 300.

The slurry filter replacement process, which may be manually performed in related operating stations, may be performed in an unmanned manner by using an automated system that may include the slurry filter replacement robot 200. Consequently, aspects of the present disclosure may provide for preventing and/or mitigating adverse effects on the human operators that may occur during a manual replacement process, and/or preventing and/or mitigating additional contamination that may occur during the manual replacement process due to the operation of the human operator.

In addition, the slurry filter replacement robot 200 may be applicable to an operating environment in which the existing slurry filter may be disposed. For example, although the present disclosure may focus on a slurry filter replacement operation that may be performed at the operating station 100, the present disclosure is not limited thereto, and the slurry filter replacement operation may also be applicable in an existing slurry supply device. That is, the slurry filter replacement robot 200 may have an advantage in that the slurry filter replacement robot 200 may be applicable to an existing slurry supply device because the installation cost is not excessively high and the volume thereof is not relatively large.

For example, since the one or more manipulators 300 included in the slurry filter replacement robot 200 may perform various operations by using the arm 400 and the robot tool 500, it may be possible to identify a precise position needed for the replacement operation through a robot vision 550 connected to one side of the arm 400, and to adjust an amount of force and/or torque that may be applied.

Continuing to refer to FIG. 1, the operating station 100 may be and/or may include a space where the first filter 1 is disposed and the operation of replacing the first filter 1 with the second filter 2 is performed.

The operating station 100 may include an operating table 110, a head 120 disposed on the operating table 110 and coupled with the first filter 1 and the second filter 2, a ball 130 surrounding the first filter 1 and the second filter 2 coupled with the head 120, and a nut 140 disposed between the ball 130 and the head 20 and coupling the ball 130 to the head 120.

The operating station 100 may further include a housing 112 that may accommodate the operating table 110 by surrounding the entire operating table 110, and a cleaning device 150 disposed inside the housing 112 and cleaning the ball 130 and the head 120.

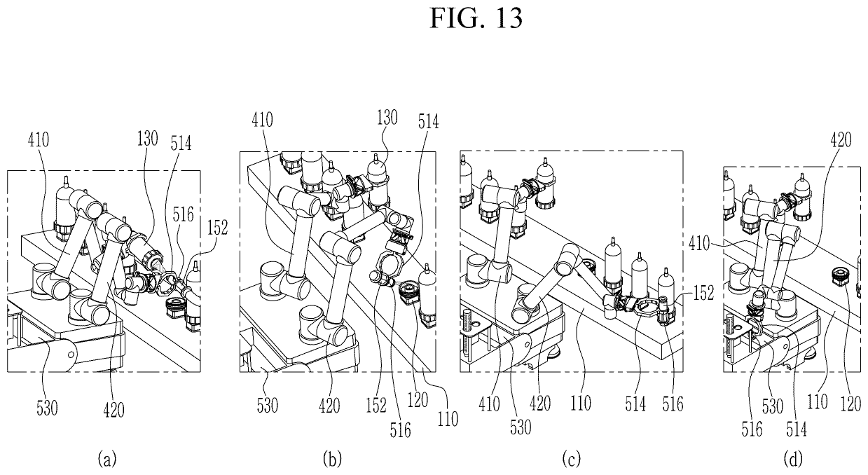

FIG. 1 shows a cleaning hose 152 as an embodiment of the cleaning device 150. A process in which the slurry filter replacement robot 200 cleans the ball 130 and the head 120 by using the cleaning hose 152 is described with reference to FIG. 13.

As shown in FIGS. 1 and 2, the robot tool 500 connected to the arm 400 of the slurry filter replacement robot 200 may include a gripper 510 and an adjuster 520.

The gripper 510 may serve to grip the ball 130, the nut 140, the first filter 1, and the second filter 2 disposed on the operating station 100.

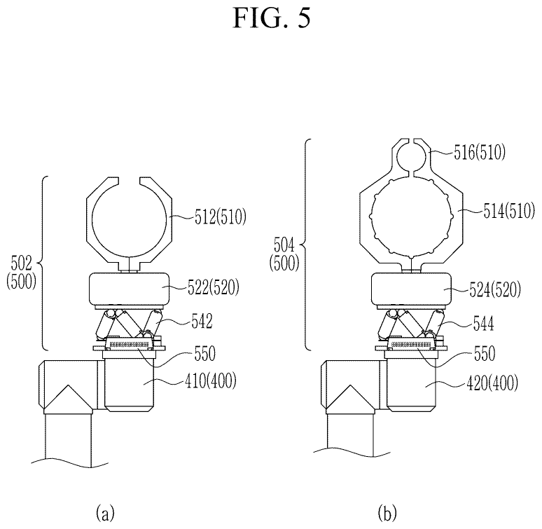

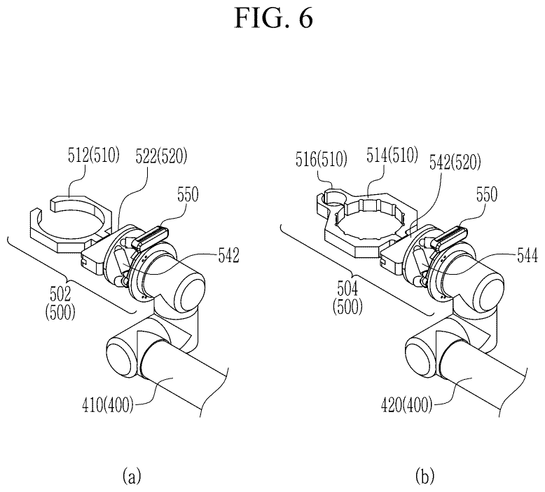

The adjuster 520 may have one side connected to the gripper 510 and another side connected to the arm 400, and may serve to adjust the gripper 510. An example of a structure of the robot tool 500 is described with reference to FIGS. 5 and 6.

In an embodiment of the slurry filter replacement robot 200 as described above, the number of manipulators 300 is not limited, and the one or more manipulators 300 are included.

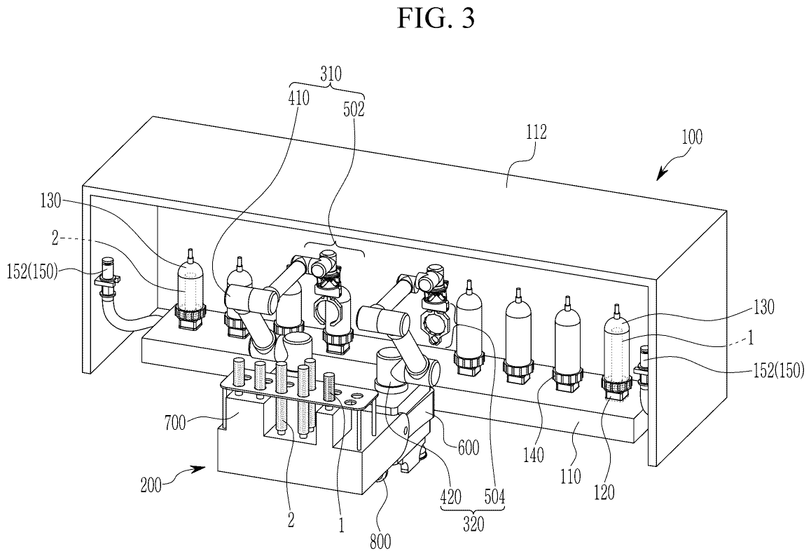

FIG. 3 is a diagram showing the overall configuration of a slurry filter replacement robot, according to an embodiment.

The slurry filter replacement robot 200 shown in FIG. 3 may include two (2) manipulators (e.g., a first manipulator 310 and a second manipulator 320, hereinafter generally referred to as “300”).

Compared to the embodiments shown with reference to FIG. 1 in which the number of manipulators 300 is not specified, the embodiments shown in FIG. 3 may be different in that the number of manipulators 300 is defined. The slurry filter replacement robot 200, as shown in FIG. 3, may be and/or may include a double-arm robot arm having two arms (e.g., a first arm 410 and a second arm 420).

As shown in FIG. 3, the slurry filter replacement robot 200 may replace the first filter 1 at the operating station 100 where the first filter 1 is disposed.

The operating station 100 may include the operating table 110, the head 120 disposed on the operating table 110, the ball 130 surrounding the first filter 1 and the second filter 2 coupled with the head 120, and the nut 140 disposed between the ball 130 and the head 20 and coupling the ball 130 to the head 120.

The slurry filter replacement robot 200 may be in the form of the double-arm robot arm, and may include a first manipulator 310 including a first arm 410 and a first robot tool 502 connected to one side of the first arm 410 and a second manipulator 320 including a second arm 420 and a second robot tool 504 connected to one side of the second arm 420.

The slurry filter replacement robot 200 may include a support frame 600 disposed in a lower part of the first manipulator 310 and the second manipulator 320, a loader 700 loading the first filter 1 and the second filter 2 connected to the support frame 600, and a mover 800 disposed in a lower part of the support frame 600 and configured to move the support frame 600. The slurry filter replacement robot 200 may be capable of horizontal movement through the mover 800, and may move closer to and/or away from the operating station 100 to replace a slurry filter.

In the case of the slurry filter replacement robot 200 being in the form of the double-arm robot arm, the second manipulator 320 may serve to replace the first filter 1 disposed on the operating station 100 with the second filter 2 disposed on the loader 700.

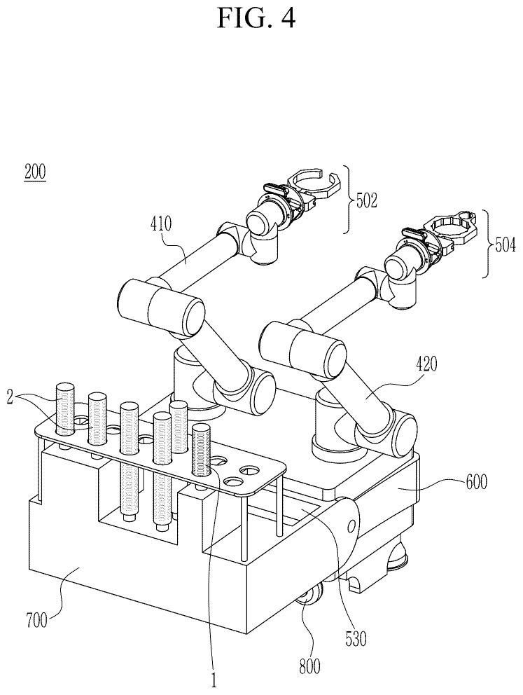

FIG. 4 is a diagram illustrating the slurry filter replacement robot of FIG. 3, according to an embodiment. FIG. 5 is a diagram depicting manipulators of the slurry filter replacement robot of FIG. 4, according to an embodiment. FIG. 6 is a diagram illustrating the manipulators of the slurry filter replacement robot of FIG. 4, according to an embodiment.

Referring to FIGS. 4 to 6, the gripper 510 of the slurry filter replacement robot 200 may include a first gripper 512 that grips the ball 130, a second gripper 514 that grips the nut 140, and a third gripper 516 that grips the first filter 1 and the second filter 2.

In the slurry filter replacement robot 200, the first manipulator 310 may include the first gripper 512 that grips the ball 130, a first adjuster 522 having one side connected to the other side of the first gripper 512 and configured to adjust the gripper 512, and the first arm 410 connected to the other side of the first adjuster 522 and having the form of a multi-joint arm.

The second manipulator 320 may include the second gripper 514 that grips the nut 140, the third gripper 516 having the other side connected to one side of the second gripper 514 and grips the first filter 1 and the second filter 2, a second adjuster 524 having one side connected to the other side of the second gripper 514 and configured to adjust the second gripper 514 and the third gripper 516, and the second arm 420 connected to the other side of the second adjuster 524 and having the form of the multi-joint arm.

The slurry filter replacement robot 200 may further include a gripper cleaner 530 that cleans the third gripper 516. The third gripper 516 grips the first filter 1, separates the first filter 1 from the head 120, loads the first filter 1 on the loader 700, and grips the second filter 2 loaded on the loader 700, and couples the second filter 2 to the head 120 of the operating table 110.

In a process of the third gripper 516 gripping the first filter 1, since there is a possibility that the third gripper 516 may be contaminated, before gripping the second filter 2, the gripper cleaner 530 may clean the third gripper 516.

As shown in FIG. 3, the operating station 100 may further include the housing 112 that accommodates the operating table 110, and the cleaning hose 152 disposed inside the housing 112, and the third gripper 516 of the slurry filter replacement robot 200 may grip the cleaning hose 152.

The third gripper 516 may grip the cleaning hose 152 and clean the inside of the ball 130 and the head 120 while the first filter 1 is separated, as described with reference to FIG. 13.

As shown in FIGS. 5 and 6, the adjuster 520 of the slurry filter replacement robot 200 may include the first adjuster 522 that adjusts the first gripper 512, and the second adjuster 524 that adjusts the second gripper 514 and the third gripper 516.

The other side of the first gripper 512 may be connected to one side of the first adjuster 522, the other side of the second gripper 514 may be connected to one side of the second adjuster 524, and the other side the third gripper 516 may be connected to one side of the second gripper 514.

According to an embodiment, as shown in FIGS. 5 and 6, the manipulator 300 may further include adaptation sensors 542 and 544 between the arm 400 and the robot tool 500. The first adaptation sensor 542 may be disposed between the first arm 410 and the first robot tool 502, and the second adaptation sensor 544 may be disposed between the second arm 420 and the second robot tool 504.

For example, the manipulator 300 may further include the first adaptation sensor 542 disposed between the first adjuster 522 and the first arm 410, and the second adaptation sensor 544 disposed between the second adjuster 524 and the second arm 420. The first adaptation sensor 542 and the second adaptation sensor 544 serve to compensate for position errors that may occur during a gripping process of the gripper 510.

The first adaptation sensor 542 may provide adaptability between the first gripper 512 and the first adjuster 522, and may include a force-torque (F/T) sensor capable of measuring force and/or torque.

The F/T sensor may have adaptability of several millimeters (mm) between the gripper 510 and the adjuster 520, and may be designed as a parallel mechanism. According to an embodiment, the first adaptation sensor 542 may further include a strain gauge and a capacitance measurement unit, and may monitor force and torque in 6 axes (e.g., 3 linear axes and 3 rotational axes) through the strain gauge and the capacitance measurement unit.

For example, the F/T sensor may be used to compensate for large internal forces that may occur upon coupling components in the 6 axes and potentially prevent and/or minimize occurrence of internal forces. At the same time, the gripper 510 may enable active position compensation, by measuring force and torque generated between the robot tool 500 and its surroundings. In addition, various coupling operations performed during the replacement process of the slurry filter may be precisely performed, by controlling force and position to minimize internal forces.

The second adaptation sensor 544 may provide adaptability between the second gripper 514 and the second adjuster 524, and may include an F/T sensor having adaptation capable of measuring force and/or torque. The second adaptation sensor 544 may also provide adaptability between the third gripper 516 and the second adjuster 524.

The F/T sensor may be used to stably perform a slurry filter replacement operation while absorbing and/or controlling a negative tolerance of an O-ring and contact force and impact force with a surrounding environment with respect to a chemical mechanical polishing (CMP) slurry filter replacement.

As shown in FIGS. 5 and 6, the manipulator 300 may further include the robot visions 550 disposed on one side of the arm 400. That is, the robot visions 550 may be respectively disposed on one side of the first arm 410 of the first manipulator 310 and on one side of the second arm 420 of the second manipulator 320.

The robot visions 550 may determine positions at which the gripper 510 of the robot tool 500 is to grip the ball 130, the nut 140, the first filter 1, and the second filter 2. In an embodiment, the robot vision 550 may be and/or may include one or more image sensors (e.g., cameras, video cameras, depth cameras, time-of-flight (TOF) cameras, stereoscopic cameras, or the like) to determine the position of the gripper 510. Alternatively or additionally, the robot vision 550 may include one or more additional sensors for determining the position, such as, but not limited to, global positioning system (GPS) components, accelerometers, gyroscopes, actuators, transducers, contact sensors, proximity sensors, ranging devices, or the like.

That is, the robot vision 550 disposed on one side of the first arm 410 may accurately derive the position at which the first gripper 512 of the first robot tool 502 grips the ball 130. The robot vision 550 may derive the position at which the first gripper 512 of the first robot tool 502 grips the ball 130 to within a predetermined accuracy threshold. The accuracy threshold may be predetermined based on design constraints.

In an embodiment, the robot vision 550 disposed on one side of the second arm 420 may accurately (e.g., within the predetermined accuracy threshold) derive the positions at which the second gripper 514 of the second robot tool 504 grips the nut 140, and the third gripper 516 grips the first filter 1 and the second filter 2.

The robot visions 550 respectively disposed on one side of the first arm 410 and one side of the second arm 420 may accurately derive coupling positions for coupling the ball 130, the nut 140, the first filter 1, and the second filter 2 to each other.

According to an embodiment, the robot vision 550 may be used to respectively derive gripping points and replacement positions of the first filter 1 and the second filter 2 as coordinates, and determine whether there are abnormalities in equipment and operations during a slurry filter replacement process by monitoring abnormal conditions or emergency situations in the surrounding environment.

In an embodiment, the slurry filter replacement robot 200 may further include a controller that may actively compensate for and/or control the positions of the first gripper 512, the second gripper 514, and the third gripper 516, by using force and torque information measured by the first adaptation sensor 542 and the second adaptation sensor 544. The controller may use a control algorithm to control the positions of the first gripper 512, the second gripper 514, and the third gripper 516, while simultaneously controlling the forces applied to the first gripper 512, the second gripper 514, and the third gripper 516. The controller may be embodied as various numbers of hardware, software and/or firmware structures that may execute respective functions described above, according to an example embodiment. According to example embodiments, at least one of these components may use a direct circuit structure, such as a memory, a processor, a logic circuit, a look-up table, and the like, that may execute the respective functions through controls of one or more microprocessors or other control apparatuses. Also, at least one of these components may be specifically embodied by a module, a program, or a part of code, which contains one or more executable instructions for performing specified logic functions, and executed by one or more microprocessors or other control apparatuses.

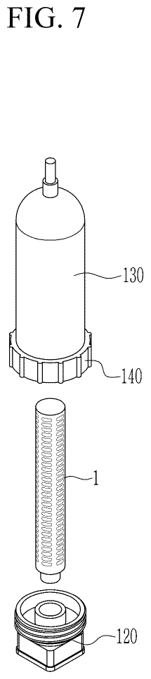

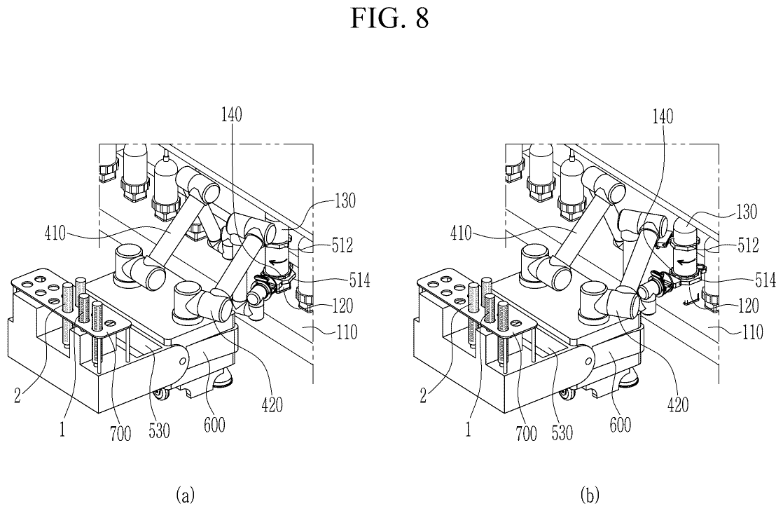

FIG. 7 is a diagram depicting a structure in which a slurry filter is coupled with an operating station in a slurry filter replacement robot, according to an embodiment. FIG. 8 is a diagram illustrating a process of coupling the slurry filter to the operating station, according to an embodiment.

FIG. 7 shows the head 120 disposed on the operating table 110 of the operating station 100, the first filter 1 coupled with the head 120, the ball 130 surrounding the first filter 1, and the nut 140 disposed between the ball 130 and the head 120.

As shown in FIG. 7, an upper part of the head 120 includes a groove coupled with a lower part of the first filter 1, and the first filter 1 may be fit into and coupled with the groove.

After the first filter 1 is coupled with the groove of the head 120, the ball 130 may be disposed to surround the outside of the first filter 1, and a lower end of the ball 130 may be coupled with the head 120. For example, the nut 140 may be disposed on a lower part of the ball 130, a screw thread may be formed on an inner surface of the nut 140 to engage with a screw groove part of the head 120, and the nut 140 and the head 120 disposed on the lower end of the ball 130 may be coupled with and separated from each other by rotating such that the screw thread and thread groove engage with each other.

That is, the nut 140 surrounding an outer circumference of the lower part of the ball 130 may be disposed in accordance with the head 120, the nut 140 may be rotated to engage the screw thread on an inner circumference of the nut 140 and the screw groove in an outer circumference of the head 120 with each other, and the nut 140 may be gripped and rotated.

FIG. 8 shows a state in which the nut 140 coupled with the lower part of the ball 130 is rotated, by using the first manipulator 310 and the second manipulator 320 of the slurry filter replacement robot 200, in order to couple the ball 130 to the head 120.

Diagram (a) of FIG. 8 shows that the first gripper 512 disposed on one side of the first arm 410 of the first manipulator 310 grips the ball 130, and the second gripper 514 disposed on one side of the second arm 420 of the second manipulator 320 grips the nut 140 coupled with the ball 130.

The nut 140 gripped by the second gripper 514 may be rotated, by moving the position of the second gripper 514 in an arrow direction shown in diagram (a) of FIG. 8, and accordingly, the nut 140 and the head 120 may be coupled with each other.

Diagram (b) of FIG. 8 shows a state in which the second gripper 514 rotates in an arrow direction. In order to rotate the second gripper 514, the position of the second arm 420 is moved, and accordingly, a direction and position of the second gripper 514 connected to one side of the second arm 420 faces change together. Accordingly, as shown in diagram (b) of FIG. 8, the nut 140 may be rotated clockwise to couple the screw thread of the nut 140 and the thread groove of the head 120 to each other.

The ball 130 and the nut 140 may be gripped by the first gripper 512 and the second gripper 514, and the nut 140 may be rotated to separate the ball 130 from the head 120, or to couple the ball 130 to the head 120. In such a process, a position at which an object to be gripped is disposed, a position at which a gripper needs to move to grip the object, or the like may be derived through the robot vision 550.

The first adaptation sensor 542 and the second adaptation sensor 544 may precisely measure and adjust the force and/or torque while the first adaptation sensor 542 provides adaptability between the first gripper 512 and the first adjuster 522, and the second adaptation sensor 544 provides adaptability between the second gripper 514 and the second adjuster 524.

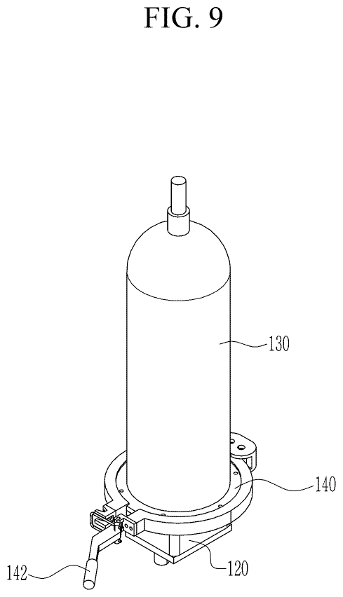

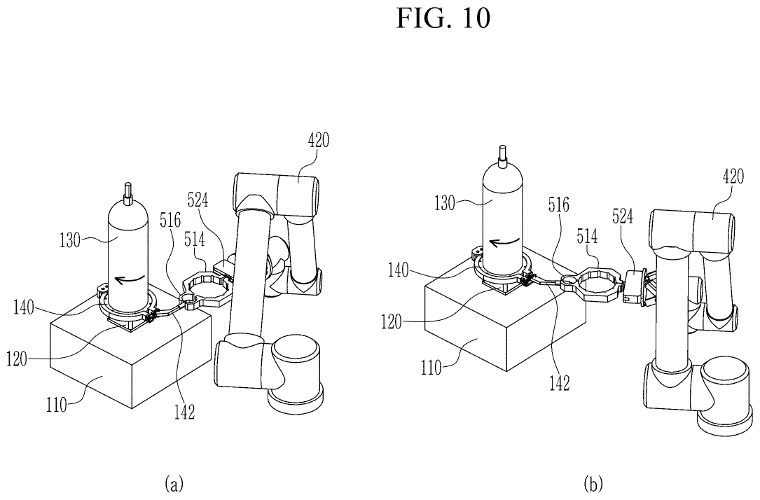

FIG. 9 is a diagram depicting a structure in which a slurry filter is coupled with an operating station in a slurry filter replacement robot, according to an embodiment. FIG. 10 is a diagram illustrating a process of coupling the slurry filter to the operating station, according to an embodiment.

Referring back to FIG. 8, the second gripper 514 may separate or couple the head 120 and the ball 130 from or to each other by rotating the nut 140 while gripping the nut 140 disposed on a lower part of the ball 130. Alternatively, in the embodiments shown in FIG. 9, a locker 142 disposed to surround the nut 140 may be further included.

As shown in FIG. 9 and diagram (a) of FIG. 10, the locker 142 may be and/or may include a clamping type, and the third gripper 516 of the second arm 420 may grip a protruding pin part of the locker 142. In addition, as shown in diagram (b) of FIG. 10, by rotating the locker 142 and the nut 140 surrounded by the locker 142 while gripping the pin part, a connection between a screw thread of the ball 130 and a screw groove of the nut 140 may be tightened.

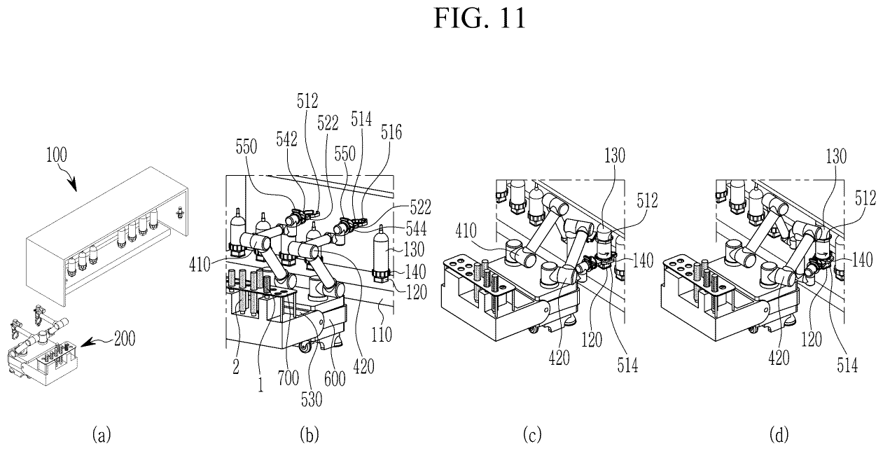

FIGS. 11 to 14 are diagrams depicting a process in which the slurry filter replacement robot replaces a slurry filter, according to an embodiment.

Referring back to FIG. 3, the slurry filter replacement robot 200 may be in the form of a double-arm robot arm having two arms of the first arm 410 and the second arm 420. FIGS. 11 to 14 show the process in which the slurry filter replacement robot 200 in the form of the double-arm robot arm replaces the first filter 1 disposed on the operating station 100 with the second filter 2 loaded on the loader 700.

Diagrams (a), (b), (c), and (d) of FIG. 11 show the process in which the slurry filter replacement robot 200 separates the ball 130 fixed to the head 120 of the operating station 100 from the head 120, from the time the slurry filter replacement robot 200 moves to the operating station 100.

Diagram (a) of FIG. 11 shows the slurry filter replacement robot 200 moving to the operating station 100. As shown in FIG. 3, the mover 800 may be disposed on a lower part of the slurry filter replacement robot 200, and thus, the slurry filter replacement robot 200 may freely move.

Diagram (b) of FIG. 11 shows the slurry filter replacement robot 200 moved to the front of the operating table 110, in order to replace the first filter 1, moving closer to the ball 130 on which the first filter 1 to be replaced is disposed.

Diagram (c) of FIG. 11 shows a state in which the first gripper 512 grips the ball 130, and the second gripper 514 grips the nut 140.

As shown in diagram (b) of FIG. 11, the robot visions 550 may be respectively connected to one side of the first arm 410 and one side of the second arm 420. The robot vision 550 may accurately derive positions at which the first gripper 512 and the second gripper 514 are to respectively grip the ball 130 and the nut 140, in a process of gripping the ball 130 and the nut 140. In this regard, diagrams (b) and (c) of FIG. 11 show processes of the robot visions 550 precisely deriving a position that is a gripping point for the first gripper 512 to grip the ball 130, and a position that is a gripping point for the second gripper 514 to grip the nut 140.

In an embodiment, the first adaptation sensor 542 disposed on the first arm 410 may measure and control force and torque while providing adaptability between the first gripper 512 and the first adjuster 522. The second adaptation sensor 544 disposed on the second arm 420 may measure force and torque while providing adaptability between the second gripper 514 and the second adjuster 524.

Alternatively or additionally, the robot visions 550 may determine respectively whether there are abnormalities in equipment and/or operations, adjust the moving positions of the first gripper 512 and the second gripper 514 by adjusting the first arm 410 and the second arm 420 according to a result of determination, and adjust the force for gripping by using the first adjuster 522 and the second adjuster 524.

Diagram (d) of FIG. 11 shows the second gripper 514 rotating the nut 140 in an opposite direction to that in diagram (b) of FIG. 8 according to the movement of the second arm 420, while gripping the nut 140 disposed on a lower part of the ball 130. The coupling between the ball 130 and the head 120 may be loosened, by the rotation of the nut 140.

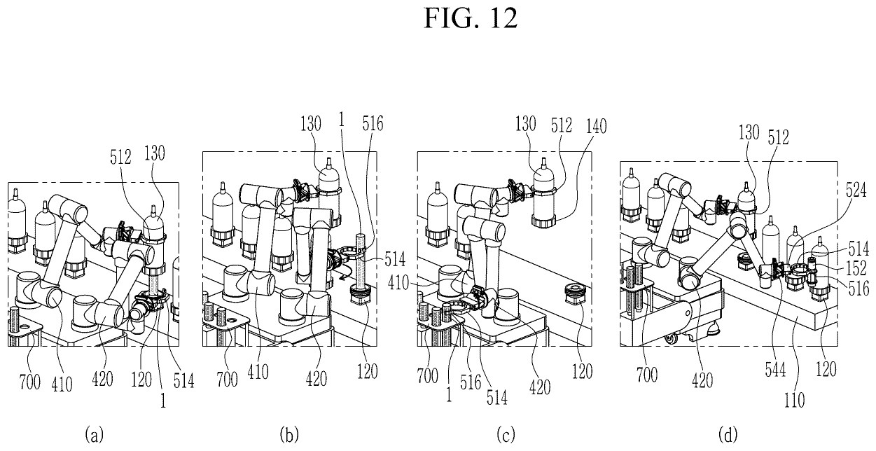

Diagrams (a), (b), (c), and (d) of FIG. 12 show processes in which the slurry filter replacement robot 200 separates the ball 130 fixed to the head 120 of the operating table 110 of the operating station 100 from the head 120, removes the first filter 1 inserted in the head 120, and grips the cleaning hose 152 for cleaning the ball 130 and the head 120.

Diagram (a) of FIG. 12 shows that, after separating the nut 140 and the head 120 from each other in diagram (d) of FIG. 11, the second gripper 514 loosely grips the nut 140, and separates the ball 130 from the head 120 as the first arm 410 connected to the first gripper 512 gripping the ball 130 moves.

Diagram (b) of FIG. 12 shows the third gripper 516 connected to an end of the second arm 420 gripping the first filter 1 inserted into the head 120 while the ball 130 is completely separated. In an embodiment, the robot vision 550 may also precisely derive a position that is a gripping point for the third gripper 516 to grip the first filter 1.

The second adaptation sensor 544 disposed on the second arm 420 may measure force and torque while providing adaptability between the third gripper 516 and the second adjuster 524. In addition, the second adaptation sensor 544 may adjust the moving position of the third gripper 516 by adjusting the second arm 420 according to a result derived from the robot vision 550, and the second adjuster 524 may adjust a gripping force of the third gripper 516.

Diagram (c) of FIG. 12 shows the second arm 420 moving while the third gripper 516 is gripping the first filter 1, and the third gripper 516 loading the first filter 1 on the loader 700.

Diagram (d) of FIG. 12 shows the third gripper 516 gripping the cleaning hose 152 disposed inside the operating station 100, in order to clean the ball 130 and the head 120, while the first filter 1 is removed from the third gripper 516.

Diagrams (a), (b), (c), and (d) of FIG. 13 show processes after cleaning the ball 130 and head 120 by using the cleaning hose 152 and before gripping the second filter 2.

Diagram (a) of FIG. 13 shows moving appropriately the second arm 420 and cleaning the ball 130 gripped by the first gripper 512 while the third gripper 516 is gripping the cleaning hose 152. The first arm 410 may also appropriately move to move a position of the ball 130 so that the ball 130 may be easily cleaned.

Diagram (b) of FIG. 13 shows moving appropriately the second arm 420 and cleaning the head 120 disposed on the operating table 110 while the third gripper 516 is gripping the cleaning hose 152.

Diagram (c) of FIG. 13 shows that, after the cleaning of the ball 130 and the head 120 is completed, the second arm 420 and the third gripper 516 move the cleaning hose 152 to the original position at which the cleaning hose 152 is initially disposed.

Diagram (d) of FIG. 13 shows cleaning the third gripper 516. The third gripper 516 grips the first filter 1 but also may grip the cleaning hose 152, and thus, there may be a possibility of contamination during the operation process.

In this regard, the slurry filter replacement robot 200 may further include the gripper cleaner 530 that may clean the third gripper 516 before the third gripper 516 grips the second filter 2.

The gripper cleaner 530 may be disposed close to the loader 700 where the second filter 2 is loaded. In this manner, contamination of the third gripper 516 may be prevented and/or mitigated by minimizing a moving time and distance, in the process of gripping the second filter 2 after the gripper cleaner 530 cleans the third gripper 516.

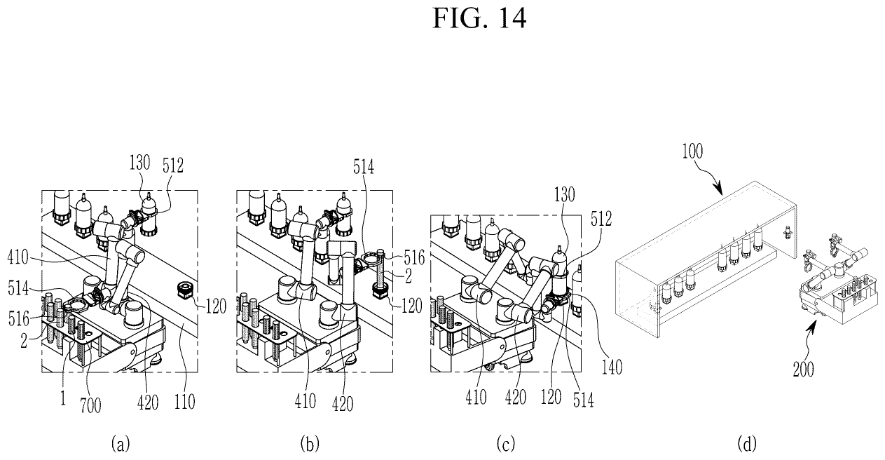

Diagrams (a), (b), (c), and (d) of FIG. 14 show the slurry filter replacement robot 200 moving away from the operating station 100 after completing the slurry filter replacement operation by coupling the second filter 2 to the head 120 of the operating table 110, and coupling the ball 130 to the head 120.

Diagram (a) of FIG. 14 shows the third gripper 516 gripping the second filter 2 loaded on the loader 700 after cleaning the third gripper 516 as shown in diagram (d) of FIG. 13.

Diagram (b) of FIG. 14 shows the third gripper 516 coupling the second filter 2 to the head 120 by inserting the second filter 2 into a groove of the head 120 of the operating table 110.

The robot vision 550 connected to one side of the second arm 420 may precisely determine the position at which the third gripper 516 may need to move in the process of gripping the second filter 2 and coupling the second filter 2 to the head 120, and the second adaptation sensor 544 disposed on the second arm 420 may provide adaptability between the third gripper 516 and the second adjuster 524.

Diagram (c) of FIG. 14 shows the second gripper 514 gripping the nut 140 after the first arm 410 moves to move the ball 130 gripped by the first gripper 512 closer to the head 120 to which the second filter 2 is coupled and place the ball 130 at a position such that the lower part of the ball 130 is aligned with the head 120.

The nut 140 and the head 120 may be coupled with each other by performing an opposite process to a separation process of the nut 140 and the head 120. In an embodiment, the second gripper 514 may rotate the nut 140 while gripping the nut 140, and accordingly, the screw thread on the inner circumference of the nut 140 and the screw groove in the outer circumference of the head 120 may be coupled with each other, and thus, the ball 130 may be fixed to the head 120.

Diagram (d) of FIG. 14 shows the slurry filter replacement robot 200 moving away from the operating station 100 after the replacement operation is completed. The slurry filter replacement robot 200 that has completed the replacement operation at the corresponding operating station 100 may move to the other operating station 100 where replacement of a slurry filter may be needed and repeatedly perform a replacement operation of the slurry filter.

The slurry filter replacement robot 200, according to the present disclosure, may differ from related cleaning processes in that an automated system is used for the slurry filter replacement process which may be manually performed in the related processes. In particular, by using the automated system that may minimize intervention of an operator, industrial accidents, such as, but not limited to, human damage, which may occur upon handling chemicals may be prevented and/or mitigated, and additional contamination caused by an operation of the operator may be prevented and/or mitigated in advance.

Furthermore, in the related processes, when an emergency situation occurs, the operator may not approach the emergency situation due to danger, which may exacerbate a problem that may make it difficult to handle the replacement operation. However, aspects of the present disclosure provide for a slurry filter replacement robot 200 that has the advantage of being able to handle the replacement operation even in various situations in that the slurry filter replacement operation may be possible without intervention of the operator.

For example, in a situation where an operator may be needed in the related art, it may be difficult for the operator to directly intervene and solve a problem by using a dedicated mechanical device during the slurry filter replacement process. However, the slurry filter replacement robot 200, according to the present disclosure, may implement an operation similar to human, and thus, intervention of the operator may be possible in the situation where the operator is essentially required may be needed.

That is, the slurry filter replacement robot 200 may be applicable even in an operation environment where the existing slurry filter is disposed. Advantageously, the slurry filter replacement robot 200 may be applicable to an existing slurry supply device because installation costs of the slurry filter replacement robot 200 may be relatively low, and its volume may not be excessively large.

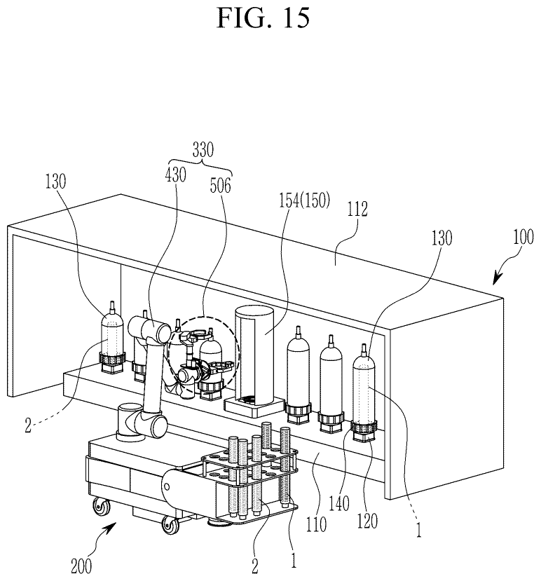

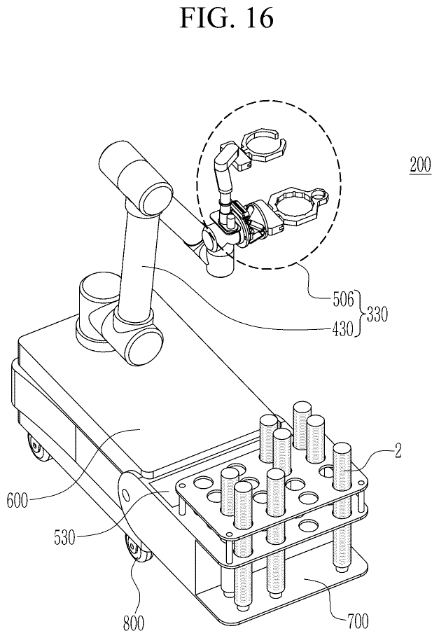

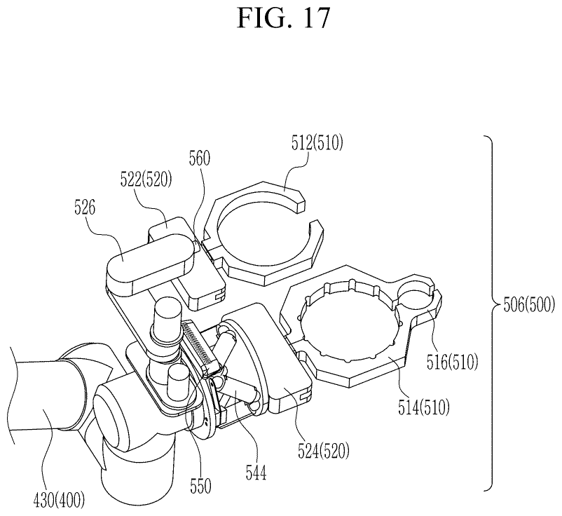

FIG. 15 is a diagram showing the overall configuration of a slurry filter replacement robot, according to an embodiment. FIG. 16 is a diagram illustrating the slurry filter replacement robot of FIG. 15, according to an embodiment. FIG. 17 is a diagram depicting a manipulator of the slurry filter replacement robot of FIG. 15, according to an embodiment.

As shown in FIG. 15, the slurry filter replacement robot 200 may replace the first filter 1 at the operating station 100 where the first filter 1 is disposed.

The slurry filter replacement robot 200 of FIG. 15 may include and/or may be similar in many respects to the slurry filter replacement robot 200 described above with reference to FIG. 3, and may include additional features not mentioned above. For example, the slurry filter replacement robot 200 shown in FIG. 15 may include only a third manipulator 330, and is in the form of a single robot arm having one arm as a third arm 430.

The operating station 100 includes the operating table 110, the head 120 disposed on the operating table 110, the ball 130 surrounding the first filter 1 and the second filter 2 coupled with the head 120, and the nut 140 disposed between the ball 130 and the head 120 and coupling the ball 130 to the head 120.

The operating station 100 may further include the housing 112 that accommodates the operating table 110, and a ball cleaner 154 disposed inside the housing 112 and accommodating and cleaning the ball 130. In an embodiment, the ball cleaner 154 may be configured to clean the inside of the ball 130. For example, the ball cleaner 154 may include hoses, sprayers, or the like to clean the ball 130.

The slurry filter replacement robot 200, according to the embodiments of FIG. 15, may include the ball 130, the nut 140, a third robot tool 506 gripping the first filter 1 and the second filter 2, and the third manipulator 330 including the third arm 430 having one side connected to the third robot tool 506.

In addition, the slurry filter replacement robot 200 may include the support frame 600 disposed in a lower part of the third manipulator 330, the loader 700 connected to the support frame 600 and configured to load the first filter 1 and the second filter 2, and the mover 800 disposed in a lower part of the support frame 600 and configured to move the support frame 600, and the third manipulator 330 may replace the first filter 1 disposed on the operating station 100 with the second filter 2 loaded in the loader 700.

Referring to FIGS. 15 to 17, the third robot tool 506 may include the first gripper 512 that grips the ball 130 and separates the ball 130 from the head 120, the second gripper 514 that grips the nut 140 and separates the ball 130 and the head 120 from each other, and the third gripper 516 that grips the first filter 1 coupled with the head 120 and replaces the first filter 1 with the second filter 2.

In an embodiment, the third robot tool 506 may include the first adjuster 522 having the other side connected to one side of the third arm 430 and configured to adjust the first gripper 512, and second adjuster 524 having the other side connected to one side of the of the third arm 430 and configured to adjust the second gripper 514 and the third gripper 516. The other side of the first gripper 512 may be connected to one side of the first adjuster 522, the other side of the second gripper 514 may be connected to one side of the second adjuster 524, and the other side of the third gripper 516 may be connected to one side of the second gripper 514.

According to an embodiment, as shown in FIG. 17, the third manipulator 330 may further include the second adaptation sensor 544 disposed between the second adjuster 524 and the third arm 430. The second adaptation sensor 544 may provide adaptability between the second gripper 514 and the second adjuster 524, and may include an F/T sensor having adaptation capable of measuring force and torque. The second adaptation sensor 544 may also provide adaptability between the third gripper 516 and the second adjuster 524.

Unlike the double-arm robot arm form shown in FIG. 3, in the case of the single robot arm form shown in FIGS. 15 to 17, the first gripper 512, the second gripper 514, and the third gripper 516 may all be connected to one third arm 430. In this regard, in order to freely move the first gripper 512, a multi-axis connector 526 may be further included in a part to which the third arm 430 and the first gripper 512 are connected.

That is, as shown in FIG. 17, the third robot tool 506 may further include the multi-axis connector 526 disposed between one side of the third arm 430 and the other side of the first adjuster 522. The multi-axis connector 526 may have a structure including three (3) to four (4) axes, for example, however the number of axes or shape of the multi-axis connector 526 is not limited in this regard.

In an embodiment, the third robot tool 506 may further include a water gun 560 disposed on the multi-axis connector 526 and configured to clean the head 120.

In the case of the single robot arm form of FIGS. 15 to 17, one third arm 430 may need to grip all the ball 130, the nut 140, the first filter 1, and the second filter 2, and thus, it may be difficult to clean the ball 130 and the head 120 by separately gripping the cleaning hose 152 as shown in FIG. 3.

Consequently, rather than the cleaning hose 152, the ball cleaner 154 may be disposed inside the operating station 100, as shown in FIG. 15, as the cleaning device 150, and the water gun 560 that cleans the head 120 may be additionally disposed in the third robot tool 506.

In an embodiment, the third manipulator 330 may further include the robot vision 550 disposed on one side of the third arm 430. The robot vision 550 may precisely determine positions at which the first gripper 512, the second gripper 514, and the third gripper 516 of the third robot tool 506 are to grip the ball 130, the nut 140, the first filter 1, and the second filter 2.

That is, the robot vision 550 may accurately derive the position at which the first gripper 512 grips the ball 130, the position at which the second gripper 514 grips the nut 140, and the position at which the third gripper 516 grips the first filter 1 and the second filter 2. In addition, the robot vision 550 may accurately derive coupling positions for coupling the ball 130, the nut 140, the first filter 1, and the second filter 2 to each other. According to an embodiment, the robot vision 550 may be used to respectively derive gripping points and replacement positions of the first filter 1 and the second filter 2 as coordinates, and determine whether there is an abnormality in equipment and/or operations during a slurry filter replacement process by monitoring abnormal conditions and/or emergency situations in the surrounding environment.

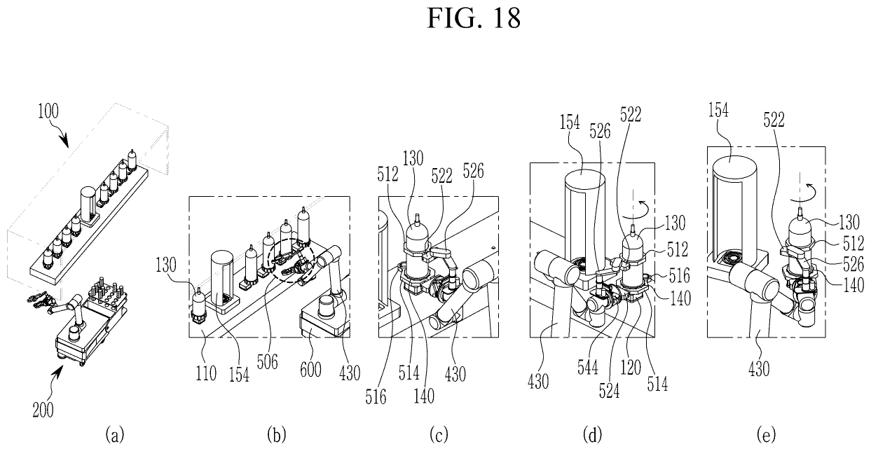

FIGS. 18 to 21 are diagrams illustrating a process in which the slurry filter replacement robot replaces a slurry filter, according to an embodiment.

The slurry filter replacement robot 200 shown in FIG. 15 is in the form of a single robot arm having one arm as the third arm 430. FIGS. 18 to 21 show the process in which the slurry filter replacement robot 200 in the form of the single robot arm replaces the first filter 1 disposed on the operating station 100 with the second filter 2 loaded on the loader 700.

Diagrams (a), (b), (c), (d), and (e) of FIG. 18 show the process in which the slurry filter replacement robot 200 separates the ball 130 fixed to the head 120 of the operating station 100 from the head 120, from the time the slurry filter replacement robot 200 moves to the operating station 100.

Diagram (a) of FIG. 18 shows the slurry filter replacement robot 200 moving to the operating station 100. As shown in FIG. 16, the mover 800 is disposed on a lower part of the slurry filter replacement robot 200, and thus, the slurry filter replacement robot 200 may freely move in a horizontal direction.

Diagram (b) of FIG. 18 shows the slurry filter replacement robot 200 moved to the front of the operating table 110, in order to replace the first filter 1, moving closer to the ball 130 on which the first filter 1 to be replaced is disposed, and shows the third robot tool 506 adjusting a position to grip the ball 130 and the nut 140.

As shown in FIG. 17, the robot vision 550 is connected to one side of the third arm 430, and may accurately derive positions at which the first gripper 512 and the second gripper 514 are to respectively grip the ball 130 and the nut 140, in a process of gripping the ball 130 and the nut 140. That is, the robot vision 550 may precisely derive a position that is a gripping point for the first gripper 512 to grip the ball 130, and a position that is a gripping point for the second gripper 514 to grip the nut 140. In an embodiment, the second adaptation sensor 544 disposed on the third arm 430 may provide adaptability between the second gripper 514 and the second adjuster 524, and measure and adjust force and torque that are generated in a process of the second gripper 514 gripping the nut 140.

The robot vision 550 may determine whether there are abnormalities in equipment and/or operations, adjust the moving positions of the first gripper 512 and the second gripper 514 by adjusting the third arm 430 according to a result of determination, and adjust the force for gripping by using the first adjuster 522 and the second adjuster 524.

Diagram (c) of FIG. 18 shows a state in which the first gripper 512 grips the ball 130, and the second gripper 514 grips the nut 140, and diagrams (d) and (e) of FIG. 18 show the process of separating the ball 130 and the nut 140 from the head 120.

Diagrams (d) and (e) of FIG. 18 show the second gripper 514 rotating the nut 140 counterclockwise according to the movement of the third arm 430, while gripping the nut 140 disposed on a lower part of the ball 130. Simultaneously and/or at a substantially similar time period with the rotation of the nut 140, the ball 130 connected to the nut 140 may also rotate counterclockwise, and the first gripper 512 gripping the ball 130 may also move. In an embodiment, the first adjuster 522 may adjust the position of the first gripper 512, and a position of an axis of the multi-axis connector 526 connected to the first adjuster 522 may be changed so that the positions of the first adjuster 522 and the first gripper 512 may be changed.

As shown in diagrams (d) and (e) of FIG. 18, the ball 130 and the head 120 may be separated from each other by rotating the nut 140.

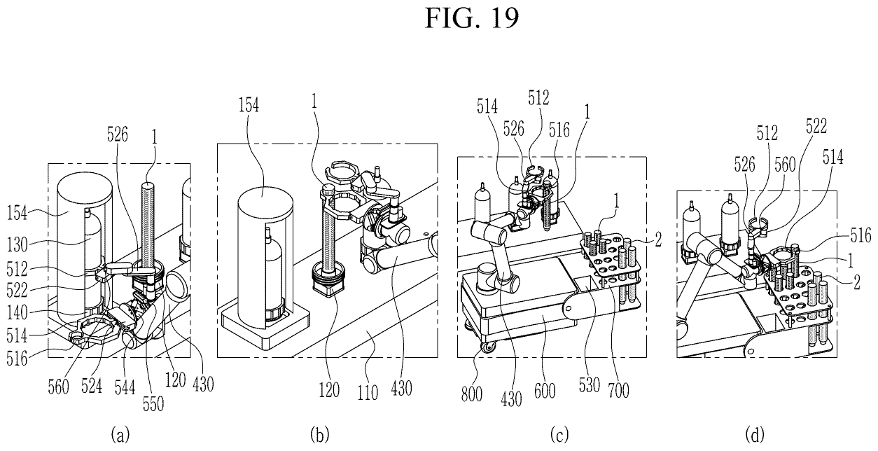

Diagrams (a), (b), (c), and (d) of FIG. 19 show the process of cleaning the ball 130 separated from the head 120, separating the first filter 1 from the head 120, and loading the first filter 1 on the loader 700.

Diagram (a) of FIG. 19 shows the first gripper 512 gripping the ball 130 separated from the head 120 and moving the ball 130 to the ball cleaner 154 disposed on an upper surface of the operating table 110. The ball cleaner 154 may clean the inside of the ball 130 disposed inside the ball cleaner 154.

Diagram (b) of FIG. 19 shows the third gripper 516 connected to an end of the third arm 430 gripping the first filter 1 inserted into the head 120 while the first gripper 512 completely separates the ball 130. In an embodiment, the robot vision 550 may also precisely derive a position that is a gripping point for the third gripper 516 to grip the first filter 1.

In addition, the second adaptation sensor 544 disposed on the third arm 430 may measure force and torque while providing adaptability between the third gripper 516 and the second adjuster 524. The second adaptation sensor 544 may adjust the moving position of the third gripper 516 by adjusting the third arm 430 according to a result derived from the robot vision 550, and the second adjuster 524 may adjust a gripping force of the third gripper 516.

Diagrams (c) and (d) of FIG. 19 show the third arm 430 moving while the third gripper 516 is gripping the first filter 1, and the third gripper 516 loading the first filter 1 on the loader 700.

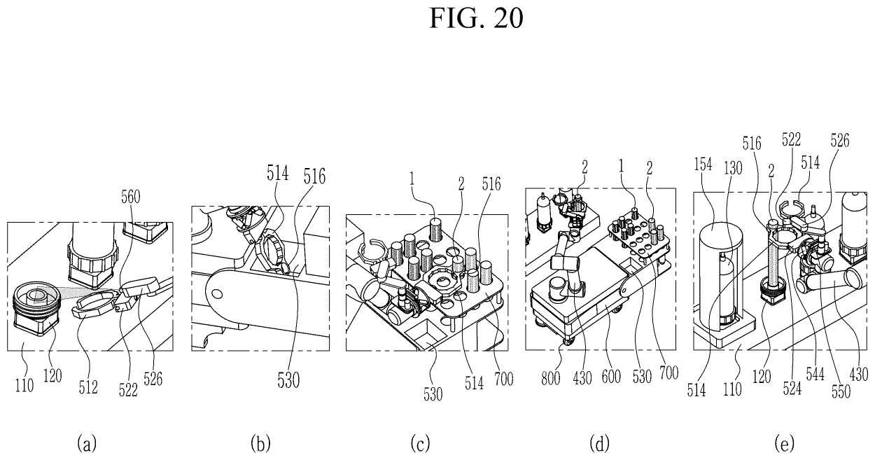

Diagrams (a), (b), (c), (d), and (e) of FIG. 20 show the process of coupling the second filter 2 to the head 120 after cleaning the head 120.

Diagram (a) of FIG. 20 shows, after removing the first filter 1 from the head 120, the water gun 560 disposed on the multi-axis connector 526 connected to the third arm 430 cleaning the head 120.

Diagram (b) of FIG. 20 shows cleaning the third gripper 516. The slurry filter replacement robot 200 may further include the gripper cleaner 530 that cleans the third gripper 516 before the third gripper 516 grips the second filter 2.

Diagram (c) of FIG. 20 shows the third gripper 516 gripping the second filter 2 loaded on the loader 700 after cleaning the third gripper 516, as shown in diagram (b) of FIG. 20, and diagram (d) of FIG. 20 shows that the third arm 430 moves to move the second filter 2 in a direction in which the head 120 is disposed. Diagram (e) of FIG. 20 shows the third gripper 516 coupling the second filter 2 to the head 120 by inserting the second filter 2 into a groove of the head 120 of the operating table 110.

The robot vision 550 connected to one side of the third arm 430 may precisely determine the position at which the third gripper 516 must move in the process of gripping the second filter 2 and coupling the second filter 2 to the head 120, and the second adaptation sensor 544 disposed on the third arm 430 may provide adaptability between the third gripper 516 and the second adjuster 524.

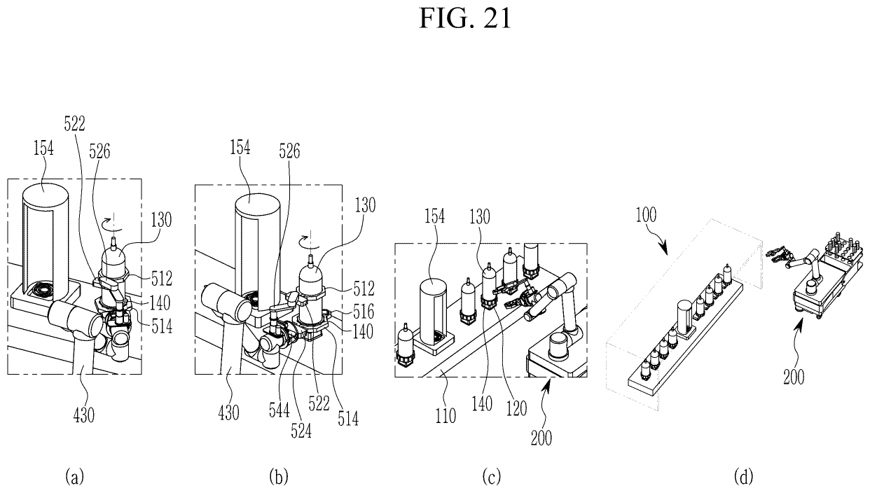

Diagrams (a), (b), (c), and (d) of FIG. 21 show the slurry filter replacement robot 200 moving away from the operating station 100, after completing a slurry filter replacement operation, by coupling the ball 130 cleaned by the ball cleaner 154 to the head 120 again.

Diagram (a) of FIG. 21 shows that the third arm 430 moves, and the first gripper 512 grips the ball 130 disposed inside the ball cleaner 154, moves the ball 130 closer to the head 120 to which the second filter 2 is coupled, and places the ball 130 at a position such that a lower part of the ball 130 is aligned with the head 120, and shows the second gripper 514 gripping the nut 140 after placing the ball 130 at the position. When the nut 140 is rotated in a direction indicated by an arrow, the nut 140 and the head 120 may be coupled with each other.

Diagram (b) of FIG. 21 shows the process of coupling the nut 140 to the head 120 by rotating the nut 140 clockwise while the second gripper 514 is gripping the nut 140. Simultaneously and/or at a substantially similar time period with the rotation of the nut 140, the ball 130 also rotates, and thus, the first gripper 512 gripping the ball 130 may also be rotated, and the first adjuster 522 and the multi-axis connector 526 connected to the first gripper 512 may also be moved together.

Diagram (c) of FIG. 21 shows that the slurry filter replacement operation is completed by coupling the ball 130 to the head 120 to which the second filter 2 is coupled, and diagram (d) of FIG. 21 shows the slurry filter replacement robot 200 moving away from the operating station 100 after the replacement operation is completed. The slurry filter replacement robot 200 that has completed the replacement operation at the corresponding operating station 100 may move to the other operating station 100 where replacement of a slurry filter is required and repeatedly perform a replacement operation of the slurry filter.

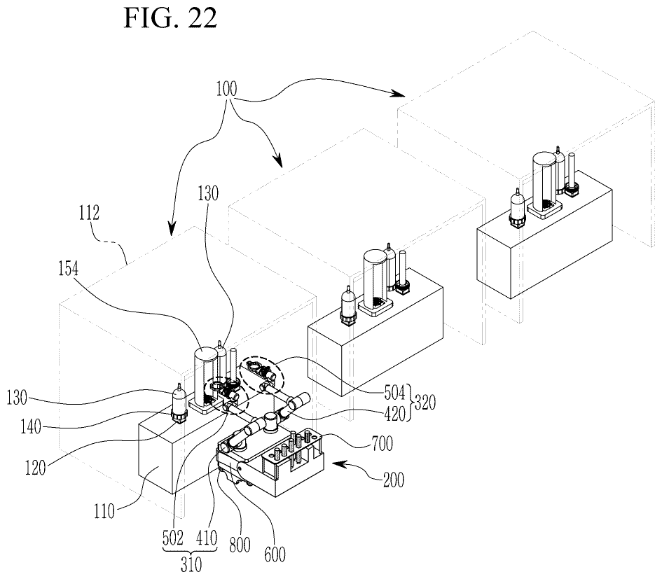

FIG. 22 is a diagram depicting a replacement process by using a slurry filter replacement robot, according to an embodiment.

The slurry filter replacement robot 200 shown in FIG. 22 may include and/or may be similar in many respects to the slurry filter replacement robot 200 described above with reference to FIG. 3, and may include additional features not mentioned above. The third gripper 516 may grip the first filter 1 and load the first filter 1 on the loader 700, and the third gripper 516 may grip the second filter 2 loaded on the loader 700 and couple the second filter to the head 120 disposed on the operating table 110.

However, unlike the operating station 100 in FIG. 3, the operating station 100 shown in FIG. 22 may have a structure in which only two (2) balls 130 are disposed inside one housing 112, and the ball cleaner 154 cleaning the ball 130 may be further disposed next to the ball 130.

The slurry filter replacement robot 200, according to the present disclosure, may not only replace the slurry filter at the designated operating station 100, but may also replace the slurry filter in an existing equipment, and the structure of the operating station 100 is not limited to FIGS. 13 and 15 and may be the similar to the structure described with reference to FIG. 22.

Although various embodiments of the present disclosure have been described above, the embodiments are not limited thereto, and various modifications may be made within the claims, the detailed description, and the accompanying drawings, and also belong to the scope of the present disclosure.

What is claimed is:

1. A slurry filter replacement robot for replacing a first filter at an operating station, the slurry filter replacement robot comprising:
one or more manipulators, each of the one or more manipulators comprising an arm and a robot tool coupled with a first side of the arm;
a support frame disposed in a lower portion of the one or more manipulators and configured to support the one or more manipulators;
a loader coupled with the support frame and configured to load the first filter and a second filter thereon; and
a mover disposed in a lower portion of the support frame and configured to move the support frame,
wherein each of the one or more manipulators is configured to replace the first filter disposed on the operating station with the second filter loaded on the loader.

2. The slurry filter replacement robot of claim 1, wherein the robot tool comprises:
a gripper configured to grip a ball of the operating station, a nut of the operating station, and at least one of the first filter or the second filter; and
an adjuster having a first side coupled with the gripper and a second side coupled with the arm, and configured to adjust the gripper,
wherein the ball of the operating station is coupled with a head disposed on an operating table of the operating station, and
wherein the nut of the operating station is disposed between the ball and the head and is configured to couple the ball to the head.

3. The slurry filter replacement robot of claim 2, wherein the gripper comprises:
a first gripper configured to grip the ball;
a second gripper configured to grip the nut; and
a third gripper configured to grip the at least one of the first filter or the second filter.

4. The slurry filter replacement robot of claim 3, wherein the adjuster comprises:
a first adjuster configured to adjust the first gripper; and
a second adjuster configured to adjust the second gripper and the third gripper.

5. The slurry filter replacement robot of claim 4, wherein a side of the first gripper is coupled with a side of the first adjuster,
wherein a first side of the second gripper is coupled with a side of the second adjuster, and
wherein a side of the third gripper is coupled with a second side of the second gripper.

6. The slurry filter replacement robot of claim 3, further comprising:
a gripper cleaner configured to clean the third gripper.

7. The slurry filter replacement robot of claim 4, wherein each of the one or more manipulators further comprise:
a first adaptation sensor disposed on a side of the first adjuster; and
a second adaptation sensor disposed on a side of the second adjuster.

8. The slurry filter replacement robot of claim 1, wherein each of the one or more manipulators further comprise:
a robot vision disposed on a second side of the arm.

9. The slurry filter replacement robot of claim 1, wherein the arm has a multi-joint arm form.

10. A slurry filter replacement robot for replacing a first filter at an operating station, the slurry filter replacement robot comprising:
a first manipulator comprising a first arm and a first robot tool coupled with a side of the first arm;
a second manipulator comprising a second arm and a second robot tool coupled with a side of the second arm;
a support frame disposed in a lower portion of the first manipulator and the second manipulator;
a loader coupled with the support frame and configured to load the first filter and a second filter thereon; and
a mover disposed in a lower portion of the support frame and configured to move the support frame,
wherein the second manipulator is configured to replace the first filter disposed on the operating station with the second filter loaded on the loader.

11. The slurry filter replacement robot of claim 10, wherein the first manipulator comprises:
a first gripper configured to grip a ball of the operating station; and
a first adjuster having a first side coupled with the a side of the first gripper, and configured to adjust the first gripper,
wherein the first arm is coupled with the second side of the first adjuster and has a multi-joint arm form, and
wherein the ball of the operating station is coupled with a head disposed on an operating table of the operating station.

12. The slurry filter replacement robot of claim 11, wherein the second manipulator comprises:
a second gripper configured to grip a nut of the operating station; and
a third gripper coupled with a first side of the second gripper and configured to grip at least one of the first filter or the second filter, and
wherein the nut of the operating station is disposed between the ball and the head and is configured to couple the ball to the head.

13. The slurry filter replacement robot of claim 12, further comprising:
a second adjuster having a first side coupled with a second side of the second gripper, and configured to adjust the second gripper and the third gripper,
wherein the second arm is coupled with a second side of the second adjuster and has the multi-joint arm form.

14. The slurry filter replacement robot of claim 12, further comprising:
a gripper cleaner configured to clean the third gripper.

15. A slurry filter replacement robot for replacing a first filter disposed at an operating station, the slurry filter replacement robot comprising:
a manipulator comprising:
a robot tool configured to grip a ball of the operating station, a nut of the operating station, and the first filter; and
a third arm having a first side coupled with the robot tool;
a support frame disposed in a lower portion of the manipulator;
a loader coupled with the support frame and configured to load the first filter and a second filter; and
a mover disposed in a lower portion of the support frame and configured to move the support frame,
wherein the manipulator is configured to replace the first filter disposed on the operating station with the second filter loaded on the loader,
wherein the ball of the operating station is coupled with a head disposed on an operating table of the operating station, and
wherein the nut of the operating station is disposed between the ball and the head and is configured to couple the ball to the head.

16. The slurry filter replacement robot of claim 15, wherein the robot tool comprises:
a first gripper configured to grip the ball and separate the ball from the head;
a second gripper configured to grip the nut and separate the ball from the head; and
a third gripper configured to:
grip the first filter coupled with the head; and
replace the first filter with the second filter.

17. The slurry filter replacement robot of claim 16, wherein the first gripper is coupled with a first side of a first adjuster,
wherein the second gripper is coupled with a first side of a second adjuster, and
wherein the third gripper is coupled with a side of the second gripper.

18. The slurry filter replacement robot of claim 17, wherein the first adjuster has a second side coupled with a second side of the third arm and is configured to adjust the first gripper, and
wherein the second adjuster has a second side coupled with a third side of the third arm and is configured to adjust the second gripper and the third gripper.

19. The slurry filter replacement robot of claim 18, wherein the robot tool further comprises:
a multi-axis connector disposed between a fourth side of the third arm and the second side of the first adjuster.

20. The slurry filter replacement robot of claim 19, wherein the robot tool further comprises:
a water gun disposed on the multi-axis connector and configured to clean the head.
